(19) United States
(12) Patent Application Publication
(10) Pub. No.: US 2025/0169030 A1
(43) Pub. Date: May 22, 2025

(54) APPARATUS AND SYSTEM FOR COOLING ELECTRONIC DEVICES

(71) Applicant: ICEOTOPE GROUP LIMITED, South Yorkshire (GB)

(72) Inventors: Neil EDMUNDS, Sheffield (GB); David AMOS, Sheffield (GB); Rupert DANIELS, South Yorkshire (GB)

(21) Appl. No.: 18/838,465

(22) PCT Filed: Feb. 16, 2023
(86) PCT No.: PCT/GB2023/050357

§ 371 Date: Aug. 14, 2024

(30) Foreign Application Priority Data
Feb. 17, 2022 (GB) 2202130.7

(51) Int. Cl. H05K 7/20

(52) U.S. Cl. CPC H05K 7/20254; H05K 7/20272; H05K 7/20436; H05K 7/20772

(57) ABSTRACT

An apparatus and system for cooling a plurality of electronic devices (25, 26) disposed on a circuit board (1) are provided. The apparatus comprises a plurality of cold plates (7, 8), each cold plate (7, 8) having a thermal interface surface for cooling an electronic device (25, 26) thermally coupled thereto. The apparatus comprises a support frame to which each of the plurality of cold plates (7, 8) is attached, the support frame configured for attachment to the circuit board so as to hold the thermal interface surfaces of the plurality of cold plates (7, 8) in thermal contact with the plurality of electronic devices (25, 26). The support frame is arranged to hold the thermal interface surface of each of the plurality of cold plates (7, 8) at a different position relative to the support frame.

### TECHNICAL FIELD

This disclosure concerns an apparatus and a system for cooling electronic devices.

### BACKGROUND

Computers, servers, and other devices used for data processing (referred to as Information Technology or IT) typically comprise printed circuit boards (PCBs). On these PCBs are small devices called Integrated Circuits (IC), which may include central processing units (CPUs), Application Specific Integrated Circuits (ASICs), Graphical Processing Units (GPUs), Random-Access Memory (RAM), etc. All of these electronic components or devices generate heat when in use. In order to maximise the performance of the IT, heat should be transferred away, in order to maintain the contents at an optimal temperature. These considerations also apply to other types of electronic devices or systems.

IT is usually housed within a case, enclosure or housing. In a server, for instance, this enclosure is sometimes referred to as the server chassis. A server chassis typically adheres to a number of industry standards that specify the height of each chassis, referred to as 1RU (one rack unit) or 1OU (one open unit), these are also abbreviated to 1U or 1OU. The smaller of the two main standards is the 1RU/1U, which is 44.45 mm or 1.75 inches in height. Such units are sometimes referred to as a “blade” server in the sense of shape and style, although it may not be necessary for such a server chassis to slot or plug into a backplane, for example.

Different server products can utilise more than one RU/OU at a time for the chassis, for example a 2U chassis uses 2 rack units. The size of each server chassis is usually kept to a minimum to maximise the amount of computing power per server rack (a server rack is the main housing that server chassis are added to). Nevertheless, despite reduced space requirements being generally desired, it is common for 3U, 4U and 5U systems to be used.

Typically, the electronic components or devices that are used on or in IT are cooled using air. This usually includes a heat sink of some kind with fins or similar being placed in contact with the chip surface either directly, or with a TIM (thermal interface material) between the two components. In addition to the heat sink, each enclosure uses a series of fans to pull air through the enclosure, removing heat from the heat sink and expelling it from the chassis. This type of heat sink is used in combination with cooling at the server facility side, such as air conditioning. This method of cooling is not especially efficient, has a high running cost, and uses large amounts of space for managing the air used for cooling.

This method of cooling IT has been used almost exclusively for mass-manufactured IT and server equipment. However, in more recent times, the peak performance of the heat generating chips has been throttled due to the limitations of cooling a device with air. As technology halves in size for the same performance every couple of years (as exemplified in Moore's law), the heat produced by chips is increasing as the footprints of components decrease. This has seen an increase in the size and complexity of heat sinks designed for air cooling. As a result, there is often an increase in the required server chassis size, thus decreasing the computing power within a single rack.

As an alternative to air cooling, liquid cooling can be used. Liquid cooling can in some cases provide a more efficient heat transfer from the electronic components or devices, and so greater cooling power. These liquids include dielectric fluids, mineral oil and water to mention a few. A number of existing approaches using liquid cooling are known. For example, International Patent Publication No. 2018/096362, commonly assigned with the present disclosure and incorporated herein by reference, describes an immersive liquid cooling approach in which a primary liquid coolant, typically a dielectric liquid, is pumped within a sealed chassis, such that the primary liquid coolant stays inside. A heat exchanger is also within the chassis and transfers heat from the primary liquid coolant to a secondary liquid coolant which flows outside the chassis (and may be shared between multiple chassis) and is typically water or water-based (advantageous as having a high specific heat capacity).

Building on this, International Patent Publication No. 2019/048864, also commonly assigned with the present disclosure and incorporated herein by reference, describes a number of types of heat sink that may be mounted on, around or adjacent to an electronic device or an electronic device may be mounted on or around the heat sink. The heat sinks define an internal volume for accumulating and retaining primary liquid coolant adjacent to the electronic device (or devices). As the primary liquid coolant flows (by pumping and/or by convection) within the chassis, it is directed to the internal volumes of the heat sinks, causing improved cooling of the electronic devices (for example, ICs getting particularly hot in operation or power supply units). Primary liquid coolant then flows out of the heat sink internal volume (for example, by overflowing and/or by flowing through holes in the volume) and collects with the remaining primary liquid coolant in the chassis, in order to cool other electronic devices (for example, other components or ICs on a PCB or mounted in other ways in the chassis). The primary liquid coolant is again cooled by a heat exchanger in the chassis and heat is transferred to a secondary liquid coolant. In this approach, the level of primary liquid coolant in the chassis can be kept low and certainly lower than the level of primary liquid coolant in the heat sink internal volume. This forms liquid cooling at multiple levels (heights), reducing the quantity of liquid coolant needed and allowing efficient single- phase (that is, liquid-phase only) cooling of the electronic devices. Since the primary liquid coolant can be expensive, difficult to contain and prone to contamination, this approach can provide significant benefits in terms of reduced cost and complexity.

International Patent Publication No. 2021/099768, also commonly assigned with the present disclosure and incorporated herein by reference, describes a cold plate having an external receptacle. The external receptacle defines a volume that can receive (for example, through a nozzle) and accumulate and/or retain a primary liquid coolant so to provide heat transfer between the primary liquid coolant on the outside of the cold plate and a secondary liquid coolant flowing through the cold plate (for example, in a conventional way). The primary and secondary liquid coolants are distinct, separate and physically isolated from one another (although thermally coupled). Systems that employ a hybrid of immersive cooling and cold plates are known.

While these known liquid cooling systems provide good performance, it would be desirable to provide an improved liquid coolant-based system with high performance and efficiency. Moreover, as circuit boards become more densely packed, it becomes challenging to position the various different heat sinks and/or cold plates in the correct positions.

### SUMMARY

Against this background, apparatus for cooling a plurality of electronic devices disposed on a circuit board in accordance with claim 1 is provided. A system for cooling a plurality of electronic devices disposed on a circuit board in accordance with claim 24 is also provided.

This disclosure relates to an apparatus for cooling a plurality of electronic devices disposed on a circuit board. The electronic devices may be chips or individual electrical components and the various chips or components can be densely packed onto a circuit board. The apparatus comprises a plurality of cold plates (such as, for example, any of the cold plates described in International Patent Publication No. 2021/099768, which is incorporated herein by reference). Each cold plate has a thermal interface surface for cooling an electronic device thermally coupled thereto, for example when brought into contact with the cold plates. A support frame is provided, to which each of the plurality of cold plates are attached. The support frame is configured for attachment (for example, by being screwed to, or by being rigidly physically coupled to) to the circuit board so as to hold the thermal interface surfaces of the plurality of cold plates in thermal contact (e.g. to allow heat transfer) with the plurality of electronic devices. The support frame is arranged to hold the thermal interface surfaces of each of the plurality of cold plates at a different position relative to the support frame. The respective position of a cold plate relative to the support frame can be any of or more of, for example, an angle relative to the support frame, a distance from the support frame (e.g. measured directly between the cold plate and its point of attachment to the support frame), and/or a lateral position along the support frame (e.g. all cold plates could be at substantially the same distance from the support frame, but spaced apart).

By attaching a plurality of cold plates to a single support frame, multiple cold plates can be held in different positions to provide cooling for multiple electronic devices in a space-efficient way. Providing a single support frame that is used to hold multiple cold plates in position allows dense arrangements of electronic devices to be cooled efficiently, since a shared support frame can take up less space on a circuit board than individual attachment mechanisms for each cold plate (e.g. one socket per cold plate). Existing solutions typically utilise one relatively large mounting structure per cold plate. Therefore, in conventional arrangements, relatively large gaps need to be provided around each electronic device to provide space for the associated mounting structure. In contrast, the present disclosure provides a single support frame so that multiple cold plates can be fixed relative to the circuit board without each cold plate requiring a dedicated mounting structure.

The positions of the cold plates are different positions, and the position of each cold plate may be a distance from the support frame and/or an angle relative to the support frame. Equivalently, for a perfectly planar circuit board, the distance and angle may be measured relative to the circuit board instead. Nevertheless, due to manufacturing tolerances, circuit boards may not be perfectly flat, so angles and distances are usually defined relative to the support frame in this disclosure. A first subset (i.e. one or a plurality) of the plurality of cold plates may be at a first distance from the support and a second subset (i.e. one or a plurality) of the plurality of cold plates may be at a second distance from the support frame, so as to permit cooling of electronic devices having different heights (or which are at slightly different heights due to imperfections in a circuit board). In the context of this disclosure, a subset of the plurality cold plates may comprise only a single cold plate, or a subset may comprise a plurality of cold plates.

Different electronic devices have different thicknesses and so the apparatus disclosed herein can allow chips with different heights to be accommodated. Similarly, chips that have upper surfaces that are not perfectly parallel with the circuit board (i.e. which are at different angles to the circuit board) can also be accommodated. For instance, an electronic device might not sit perfectly flat on a circuit board (e.g. due to the way it is installed) and so a support frame that permits cold plates to be held at slightly different positions (e.g. heights and/or angles) can advantageously allow such a device to be cooled. Moreover, whilst it might appear to be possible to cool two adjacent electronic devices with a single cold plate that spans the two electronic devices, in reality the two adjacent electronic devices are unlikely to be mounted with their upper surfaces perfectly parallel. This means that a single cold plate is unlikely to be able to simultaneously cool two electronic devices effectively due to the slight differences in angle of the electronic devices. Therefore, a single support structure that allows multiple cold plates to simultaneously cool adjacent electronic devices using cold plates and which gives the cold plates freedom to be positioned at different positions (e.g. heights and/or angles) can provide a space-efficient solution that provides good cooling for multiple devices. In generalised language, at least one cold plate, and optionally a plurality of cold plates (or even all cold plates), may be rotatably attached to the support frame, which can improve engagement with a respective electronic device.

Moreover, various electronic devices have different finishes and may not be equally flat (e.g. due to manufacturing limitations). Often, a TIM (such as metal indium, thermal paste, thermal grease, gap filler, thermal pads, thermal tape, etc.) is placed between electronic devices and heat sinks or cold plates. Manufacturing and/or mounting defects (e.g. deviations in height, angle, flatness, surface finish etc.) can prevent adequate TIM compression, which can have severe impacts on cooling. TIM is often compressed down to a thickness of 0.02 mm, meaning that microns of difference in height/angle/flatness can cause significant impacts on heat transfer. Thus, these effects imperfections also mean that it is extremely difficult to cool electronic devices reliably with a single cold plate. Thus, the support frames described herein can permit cooling of various different electronic devices by permitting multiple different cold plates at slightly different angles on a single support frame. A TIM may be provided between the electronic devices described herein and the cold plates described herein. TIM may be provided on the electronic devices and/or the cold plates.

Throughout this disclosure, first and second subsets of a plurality of cold plates are described. Nevertheless, one or more further subsets (for example, third, fourth, fifth, sixth, etc.) of the plurality of cold plates may be provided at respective distances from the support frame. The provision of a support frame arranged to hold different subsets of the plurality of cold plates at different positions relative to a support frame allows the cold plates to be held against electronic devices that have different sizes and/or different positions (for example, different heights and/or angles). By allowing multiple cold plates to be held in contact simultaneously with multiple different electronic devices, efficient cooling of a potentially large number of electronic devices in various arrangements can be achieved.

Notably, the apparatus of the present invention does not comprise a circuit board or any electronic devices. The apparatus of the present invention is a standalone component that can be fitted to an existing circuit board to cool electronic devices whose upper surfaces are at different positions (e.g. vertical positions, angles, etc.). The invention is a device suitable for attachment to a circuit board and suitable for holding cold plates near electronic devices that require cooling. For instance, the apparatus may be retrofitted.

In this disclosure, distances between the cold plates and/or the electronic devices or circuit board are sometimes described. These distances are sometimes described with reference to the circuit board and/or the electronic devices to aid visualisation, because a circuit board (and particularly a planar circuit board) provides a natural reference point for describing electronic devices having different heights. It will be appreciated that in preferred embodiments, the total distance from the top of the support frame to the bottom of the support frame will be approximately equal to the sum of: a distance from a top surface of the support frame to a thermal interface surface; a distance from that thermal interface surface to a respective electronic device; the thickness of that electronic device; and the thickness of circuit board. Therefore, for any given apparatus, the distance between a cold plate and a circuit board can be converted into a distance between a cold plate and the top of the support frame. As described previously, at its most general level, the present invention may be considered to be an apparatus comprising a plurality of cold plates and a support frame configured to hold the thermal interface surfaces of the cold plates at different distances from the support frame (i.e. the support frame rather than the circuit board can be used as the reference point for any distance measurements).

In generalised terms, therefore, aspects of the present disclosure may be described as an apparatus for cooling a plurality of electronic devices disposed on a circuit board. The apparatus comprises: a plurality of cold plates, each cold plate having a thermal interface surface; and a support frame to which each of the plurality of cold plates is attached. The support frame is arranged to hold the thermal interface surface of at least a first cold plate at a first position relative to the circuit board and to hold the thermal interface surfaces of at least a second cold plate at a second position relative to the circuit board. The first and second distances may be different. In the context of this disclosure, the term circuit board is intended to encompass any substrate or surface onto which electronic devices, such as electronic components and chips, may be disposed. A circuit board may be a PCB, a breadboard, a stripboard, or any other type of surface onto which electronic devices can be mounted.

Where multiple subsets of cold plates are described herein, a first subset may be at a first position (e.g. distance from the support frame and/or angle relative to the support frame), a second subset may be at a second position, a third subset may be at third position, and so on. Thus, the subsets of the plurality of cold plates may each comprise one or more cold plates at different positions relative to a support frame. Nevertheless, there may be some subsets at the same height (or angle). For instance, a first subset could be at a first distance, a second subset could be at a second distance, and a third subset may be at the first distance. The precise distances between the cold plates and the support frame will depend upon (and might be adjustable to accommodate) the particular arrangement of electronic devices.

Liquid cooling may be employed in the present disclosure, with multiple cold plates advantageously being combined into one assembly, with each cold plate providing liquid cooling to one or multiple heat sources (e.g. electronic devices). Coolant can be fed to any particular subset of the cold plates either in parallel or in series, depending upon the pipework routing. Thus, the cold plates described in this disclosure may define an internal volume arranged to receive liquid coolant into the internal volume, so as to transfer heat from an electronic device to the internal volume. The internal volume may have a closed top, for instance to prevent coolant leaking out of the cold plate. One or more cold plates may have an open top, for instance to allow coolant to overflow from the cold plate (as described in International Patent Publication No. 2019/048864), so that the coolant comes into contact with and cools other components disposed at a lower levels on the circuit board. Some of the cold plates in this disclosure can be considered a composite of a heat sink (which provides a thermal interface surface for cooling electronic device(s)) and an upper portion that retains the liquid coolant and holds the liquid coolant on the lower heat sink portion of the cold plate. The upper portion can be a closed structure, or can be an open structure with retaining vertical walls but no top surface. At least one cold plate may comprise a base and a retaining wall that together define a volume for holding liquid coolant, which may be arranged such that liquid coolant overflows over the retaining wall.

The path of liquid coolant may be determined by the arrangement of connecting pipes or hoses to the individual cold plates. For instance, coolant may be used to cool components whose temperatures are closest to their maximal operating temperatures first, with the used coolant then being fed to other cold plates to cool components that are less close to their maximal operating temperatures. Therefore, the flow path can be optimised based on the temperature limits of the individual heat sources. For instance, an electronic device (e.g. a chip) that has a relatively low temperature limit could be cooled first, followed by the remaining chips. In some embodiments of the disclosure, a plurality of outer chips (e.g. optical modules) are arranged around one or more inner chips. In such embodiments, the outer chips are cooled in parallel first (i.e. cold plates in thermal contact with the outer chips receive liquid coolant in parallel with each other) and then the exit flow of those outer cold plates is passed into a central cold plate above the inner chip (which may be, for example, an ASIC chip), before the coolant leaves the cold plates.

It can be difficult to cool a circuit board (e.g. a printed circuit board or PCB) with multiple electronic devices (e.g. chips) at different positions (e.g. heights or angles) using a single cold plate. The same is true for various other arrangements of electronic devices on a surface (such as a breadboard or a stripboard), with multiple electronic devices at different positions. Manufacturing tolerances of cold plates and error stack at the chip-heat sink interface can make it difficult to position cold plates with enough accuracy to cause the cold plates to be brought into contact with the various components at different positions. Thus, some embodiments of the disclosure are directed to addressing these challenges and provide an apparatus that incorporates multiple cold plates that can be moved independently of one another. Being able to control the positions of cold plates independently helps to overcome these difficulties and allows improved contact between the heat sources and heat sinks (e.g. cold plates). This independence can be used to achieve improved thermal interface material (TIM) compression, resulting in better cooling performance.

In some embodiments, to attain improved TIM compression, a circuit board with electronic devices thereon and a plurality of cold plates may be forced together using two separate plates (which may be formed from steel) and which are referred to in this disclosure as lower and upper compression plates. The compression plates force the electronic devices against the thermal interface surfaces of the cold plates. Common heat sinks require a baseplate and a socket for alignment prior to compression, but this can be difficult to implement on certain chip layouts. Thus, a cold plate may be attached to the upper compression plate to form a cold plate assembly. The purpose of the upper compression plate is therefore to first locate the cold plates in their correct position and then to apply a compressive force on the electronic devices. Compression limitation may be achieved by providing standoffs (or other spacers/projections) between the two compression plates. The upper and lower compression plates may be considered to be first and second portions of the support frame and there is no requirement for the plates to be flat (although the plates are flat in some embodiments). The standoffs may also be considered to be part of the support frame of the apparatus described in this disclosure.

As discussed previously, some embodiments of the disclosure allow manufacturing and/or mounting imperfections to be accommodated. One feature that is advantageous for providing such flexibility is the provision of resilient members, such as springs, between the cold plates and the upper compression plate. The resilient members may be compressed by a specified displacement to attain a desired TIM activation pressure. The pressure may be selected to achieve good thermal coupling by bringing the cold plates into abutment with the electronic devices. Different cooling requirements for different electronic devices may mean that higher compression might be desired for one component than for others, but traditional mounting methods (e.g. springs in each corner of a single cold plate) do not easily allow multiple cold plates in a dense area to be cooled by cold plates efficiently. In embodiments of the present disclosure, resilient members (e.g. springs) can allow cold plates to have freedom to rotate to be in perfect alignment with an imperfectly-mounted or imperfectly-finished electronic device. Moreover, in some embodiments, the pressure provided may be fine-tuned using threaded disc-insert(s), which sit within the upper compression plate. For example, by screwing the insert downwards (i.e. towards the electronic devices beneath the cold plates), the amount by which the resilient member is compressed is increased, so a greater compressive force is achieved. This adjustability may be used to account for manufacturing errors that result in chips sitting at different positions (e.g. height and angles) and/or may be used to ensure that chips are not subjected to excessive forces.

As mentioned previously, some embodiments of the disclosure employ liquid cooling (although the cold plates described herein do not necessarily need to be liquid-cooled). The liquid cooling can be provided by a closed loop cooling arrangement in which coolant is constrained to pass through each cold plate. In some embodiments, a hybrid arrangement can be provided. In a hybrid arrangement, some electronic components are immersed or at least partially submerged in coolant in a chassis (e.g. coolant that has been allowed to overflow or spill out from some cold plates), while other components are held in contact with cold plates that have liquid coolant flowing through (although the cold plates need not have liquid flowing through). In any case, each cold plate that uses liquid cooling may have a separate inlet and outlet port, for receiving coolant and for allowing coolant to leave cold plate.

One or more protrusions, such as fins or skiving, may be provided within the cold plates to improve heat transfer from the electronic devices to the coolant. In preferred embodiments, a gasket is positioned within each cold plate between a lower copper skived heat sink and the upper part of the cold plate, which is typically made from steel (although other materials may be used). Although skiving is employed, other protrusions (such as pins, rods, fins, baffles, channels, etc.) may be used. The gasket prevents coolant from bypassing the projections in the internal volume defined by the cold plate. The gasket therefore maximises the wetted area of the heat sink, which enhances cooling performance. Bosses on a surface of the gasket may be provided, to allow the gasket to be located correctly and to prevent the gasket from being disturbed (e.g. washed away) by coolant.

The cold plates described in the present disclosure can be provided as standalone components. In particular, the disclosure provides a cold plate for cooling an electronic device, the cold plate defining an internal volume arranged to receive liquid coolant into the internal volume for transferring heat from the electronic device to the internal volume, wherein the cold plate comprises: a thermal interface surface for cooling the electronic device thermally coupled thereto; one or more protrusions on an internal surface of the internal volume; and a gasket arranged to constrain the liquid coolant to flow around the one or more protrusions. An interior surface of the cold plate and/or a surface of the gasket may comprise one or more bosses arranged to engage a complementary surface of the gasket or interior surface of the cold plate, so as to align the gasket within the cold plate. Such a cold plate can be used to cool an electronic device efficiently.

In some embodiments, the present disclosure provides: an apparatus for cooling a plurality of electronic devices disposed on a circuit board, the apparatus comprising: a plurality of cold plates, each cold plate having a thermal interface surface for cooling an electronic device thermally coupled thereto; and a support frame to which each of the plurality of cold plates is attached, the support frame configured for attachment to the circuit board so as to hold the thermal interface surfaces of the plurality of cold plates in thermal contact with the plurality of electronic devices; and wherein the support frame comprises a first plate and an opposing second plate, said second plate being displaced with respect to the first plate, wherein the first plate is moveable such that a displacement between the first and the second plates can be varied, and at least one of the plurality of cold plates is rotatably attached to the first plate.

In respect of each aspect disclosed in the present disclosure, where structural features of an apparatus are described, methods for manufacturing and/or operating those features may additionally be provided. Combinations of aspects are also possible. Moreover, combinations of specific features of the apparatus are also disclosed, where such combinations are compatible. Specific examples of such combinations are described purely by way of example.

### LISTING OF FIGURES

The disclosure may be put into practice in a number of ways and preferred embodiments will now be described by way of example only and with reference to the accompanying drawings, in which:

FIGS. 1A and 1B show isometric views of an apparatus for cooling electronic devices in a first embodiment;

FIGS. 2A, 2B and 2C show isometric and side views of a portion of the apparatus of the first embodiment;

FIGS. 3A, 3B, 3C, 3D, 3E and 3F show isometric, plan and side views of the cold plates of the apparatus of the first embodiment;

FIGS. 4A and 4B show isometric views of a portion of the apparatus of the first embodiment;

FIGS. 5A, 5B and 5C show isometric, plan and side views of a portion of the apparatus of the first embodiment;

FIGS. 6A and 6B show isometric views of the cold plates of the apparatus of the first embodiment; and

FIG. 7 shows a heat sink that can serve as any of the cold plates of the first embodiment.

### DETAILED DESCRIPTION

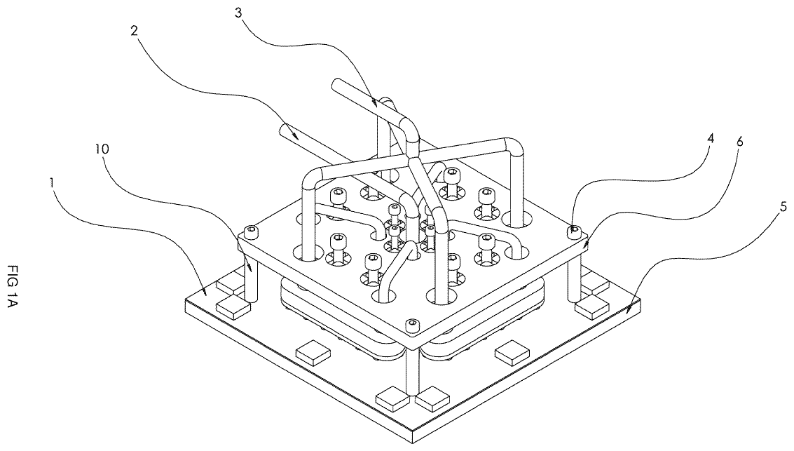

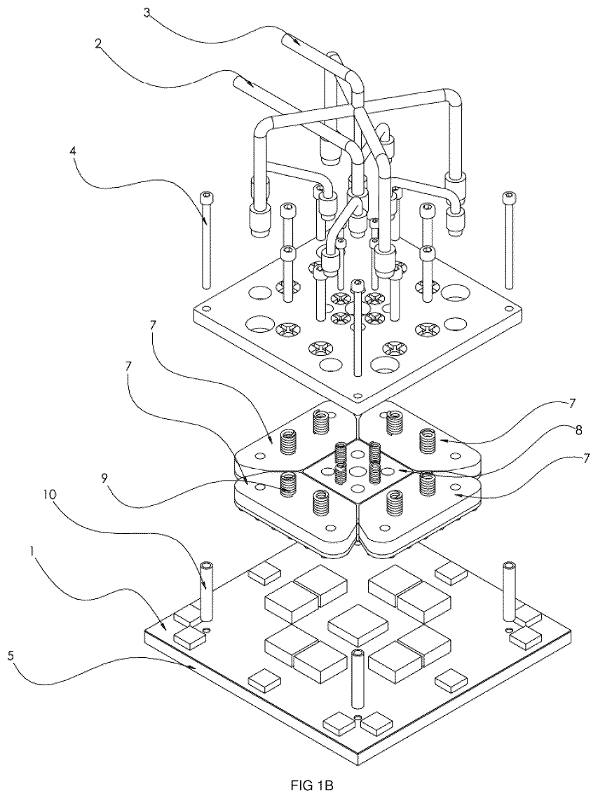

FIGS. 1A to 6B show a first embodiment of an apparatus for cooling a plurality of electronic devices 25, 26 disposed on a circuit board. In generalised terms, the apparatus comprises a plurality of cold plates 7, 8. Each cold plate 7, 8 has a thermal interface surface for cooling an electronic device 25, 26 thermally coupled thereto. The apparatus comprises a support frame to which each of the plurality of cold plates is attached. The support frame is configured for attachment to the circuit board, so as to hold the thermal interface surfaces of the plurality of cold plates 7, 8 in thermal contact with the plurality of electronic devices 25, 26. Moreover, the support frame is arranged to hold the thermal interface surfaces of a first subset of the plurality of cold plates 7, 8 at a first position relative to the support frame (and hence also the circuit board, since the support frame is attached to the circuit board) and to hold the thermal interface surfaces of a second subset of the plurality of cold plates 7, 8 at a second position relative to the circuit board (and hence also the circuit board, since the support frame is attached to the circuit board). The first subset of the plurality of cold plates may be considered to be the cold plates 7 and the second subset of the plurality of cold plates may be considered to be the cold plates 8.

In FIG. 1A, an isometric view of such an apparatus is shown. In FIG. 1A, a Multi Heat Source Cold Plate assembly (described herein as an MHSC) is mounted to a circuit board 1, in accordance with a first embodiment. Provided beneath the circuit board 1 is a plate 5 (which is made from steel, although other materials could be used, such as other metals like aluminium, or plastics such as nylon, glass-reinforced plastic, composites, etc.). The plate 5 is also referred to throughout this disclosure as a lower compression plate. The plate 5 supports a PCB and is separated from the circuit board 1 by a thin layer of insulation. This layer of insulation ensures that there is no metallic (i.e. thermal and/or electrical) contact between the plate and circuit board 1.

Unlike most heat sink assemblies, this design does not use a socket to locate heat sinks in position. Instead, the first 7 and second 8 subsets of the plurality of cold plates 7, 8 in this embodiment are all attached to an upper compression plate 6 that is bolted using bolts 4 to the lower compression plate 5 through the circuit board 1. This ensures correct alignment of the cold plates 7, 8 relative to the chips 25, 26 on the PCB. Thus, this embodiment comprises a support frame that comprises two distinct portions: a first portion, which is the upper plate 6 to which the cold plates 7, 8 are attached, and a second portion, which is the lower plate 5. This support frame acts to hold the thermal interface surfaces (that is, the lower surfaces of the cold plates, which are on the opposite side of the cold plates to their points of attachment to the support frame) of the cold plates 7, 8 in thermal contact with the electronic devices 25, 26. In this embodiment, the thermal interface surface is the bottom surface of the lower portions 18, 23 of the cold plates, which are brought into contact with the electronic devices 25, 26.

In a general sense, the support frames of this disclosure may comprise a first portion (e.g. a first plate, such as the compression plates described previously) to which each of the plurality of cold plates are attached and a second portion (e.g. a second plate, such as the compression plates described previously) that opposes the first portion. The first portion may be for attachment to a circuit board and the second portion may be for holding the cold plates in position. Preferably, the first portion and the second portion of the support frame are configured to be drawn together (e.g. they are together configured for attachment to the circuit board), so as to hold the thermal interface surfaces of the plurality of cold plates in thermal contact with the plurality of electronic devices. Thus, the support frame may be configured to compress the plurality of electronic devices between the plurality of cold plates and the circuit board, which can ensure that good thermal contact is maintained between the electronic devices and the cold plates. For instance, the first and second portions may effectively clamp the circuit board, so as to hold the cold plates in contact with the electronic devices. Insulation may be provided on the support frame, to insulate (electrically and/or thermally) the support frame from the circuit board.

Returning to the specific description of the first embodiment, FIG. 1B shows an exploded view of the MHSC assembly. In this assembly, there are five cold plates 7, 8 in total. The first subset of the plurality of cold plates is the four cold plates 7 and the second subset of the plurality of cold plates is the single cold plate 8. The second subset is a central cold plate 8 that sits above an ASIC chip 26 on the circuit board 1, and the first subset is the four outer cold plates 7 that sit above eight optical modules 25. Between the cold plates 7, 8 and the upper compression plate 6, there are provided numerous (i.e. at least one resilient member per cold plate) resilient members 9, which in this embodiment are springs 9. As the outer four bolts 4 are tightened, the cold plates 7, 8 are brought into contact with the ASIC chip 26 and the optical modules 25, which causes the springs 9 to be compressed by upper compression plate 6. The springs 9 allow the cold plates 7, 8 to rotate as they are brought into contact with the electronic devices 25, 26, which allows the cold plates to sit flush against the electronic devices 25, 26. When a resilient member 9 is compressed by being brought into abutment with an electronic device 25, 26 on a circuit board, each resilient member 9 forces the cold plate 7, 8 attached thereto away from the support frame. While the cold plates 7, 8 are attached via springs 9 in this embodiment, they could be attached via other means (e.g. screwed to or rigidly attached to) in other implementations. In some cases, leaf springs could be used.

Using the spring constant and Hooke's law (which relates the force on a spring to its spring constant and its extension or compression), it is possible to determine the displacement required to acquire a particular force (e.g. the maximal compressive force that the chip 26 of the optical modules 25 can withstand) between the cold plates 7, 8 and circuit board chips 25, 26. For instance, a TIM may be provided on the cold plates 7,8 and/or the electronic devices 25, 26, and the resilient members 9 can be tuned (either by changing their position, or by replacing with springs with a different spring constant) to achieve a desired level of TIM compression.

In the generalised terms used previously, the apparatus of this disclosure preferably further comprise one or more resilient members (such as helical or constant force springs, although rubber components could also be used) attached to at least one, and preferably each, cold plate, the one or more resilient members configured to force the respective at least one cold plate away from the support frame. The resilient members may be provided between the support frame and the cold plates. The resilient members may acts as biasers, configured to urge the cold plates away from the support frame. In cases in which the support frame comprises two portions, the resilient member may be configured to force an associated cold plate away from one of those portions. For instance, in preferred embodiments, the resilient member forces the cold plates away from an upper compression plate of the support frame and towards a lower compression plate of the support frame. When the support frames of this disclosure comprise two distinct portions, one or more resilient members may be attached to the first portion of the support frame (i.e. the portion to which the cold plates are attached). Preferably, at least one, and preferably each, cold plate is rotatably attached to the support frame (e.g. via a resilient member), which can allow manufacturing and/or mounting imperfections to be tolerated by allowing the cold plates to rotate when held against the electronic devices. Resilient members (such as springs) may be a particularly advantageous way of permitting the cold plates to rotate, to provide flexibility to accommodate variations and to optimise the compressive forces achieved. Alternative means for achieving rotation could be used such as, for example, a ball-and-socket joint.

Standoffs 10 are placed between the upper and lower compression plates 5, 6 to prevent over compression (i.e. to limit how close the two portions 5, 6 of the support frame can be brought together), which can reduce the likelihood of damaging the chips 25, 26. Together with the compression plates 5, 6 the standoffs 10 form part of the support frame. That is, the support frame is a composite structure comprising plural elements (the plates 5, 6 and the standoffs 10). Nevertheless, the support frame could be a unitary structure that could be attached (e.g. bolted or screwed) directly to a circuit board to hold the cold plates 7, 8 in thermal contact with the electronic devices 25, 26.

Thus, in a general sense, embodiments of this disclosure may comprise one or more projections between the first portion and the second portion of the support frame, the one or more projections configured to limit a distance between the first portion and the second portion of the support frame. The projections may be spacers or standoffs. The projections may be considered to be part of the support frame, such that the support frame comprises first and second opposing portions, with the third portion being the projections between the first and second portions. Advantageously, such projections can prevent excessive compressive forces from being applied to electronic devices. When the first and second portions of the support frame are drawn together, they each come into abutment with the projections. If any further compressive forces are applied, these compresses forces act on the projections instead of the electronic devices.

The support frame of the apparatus described herein could be configured for attachment to the circuit board by various means. Whilst in the shown in FIG. 1B, embodiment, the support frame comprises two plates 5, 6 that are screwed together, with the screws passing through holes in circuit board to draw the two portions 5, 6 together to clamp onto the circuit board, the support frame could be screwed directly onto a circuit board in other implementations. In any event, it is preferable that when installed, the support frame will not be moveable with respect the circuit board, and the support frame could be attached directly or indirectly to a circuit board to achieve such a rigid connection.

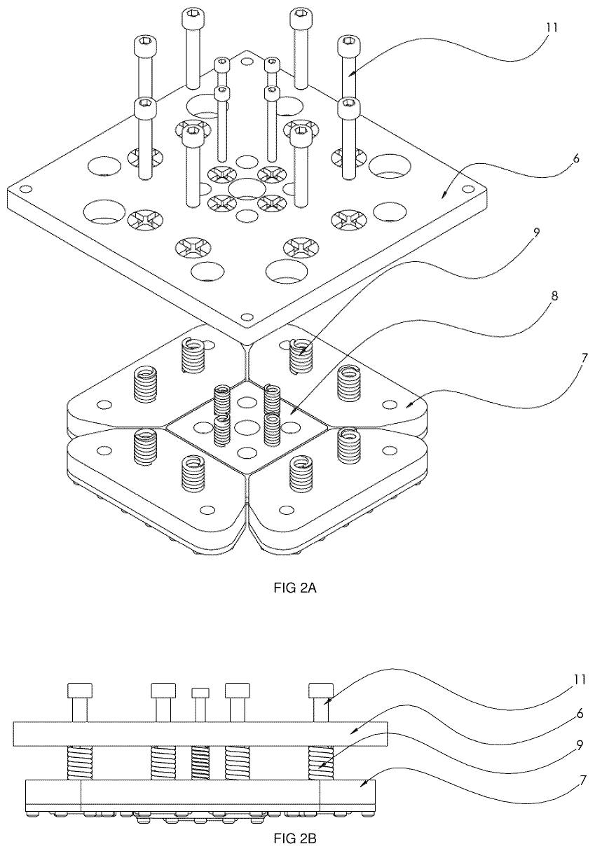

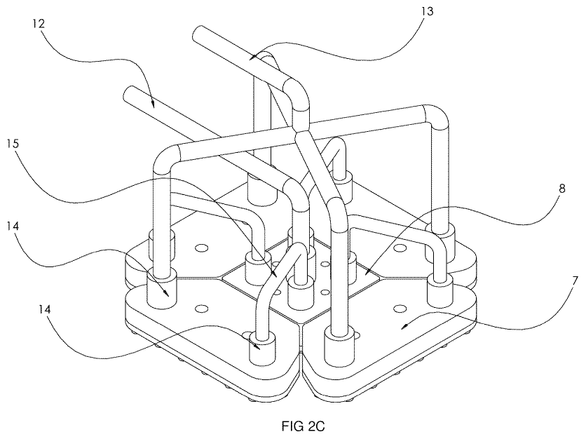

In FIG. 2A, an exploded view of the cold plates 7, 8 and upper compression plate 6 is shown. FIG. 2A demonstrates how the components are attached to each other. Location bolts 11 pass through the upper compression plate 6 and through the springs 9 into the top surface of the cold plate assemblies 7, 8. The purpose of the location bolts 11 is to keep the springs 9 captive and perpendicular between the upper compression plate 6 and the cold plates 7, 8. The bolts 11 effectively act as shafts that restrict the movement of the cold plates 7, 8. With all the cold plates 7, 8 attached to the upper compression plate 6, this forms a single assembly. Returning to the generalised terms used previously, the location bolts 11 may be described as alignment pins configured to hold resilient members in alignment.

Thus, in general terms, the apparatus described herein may comprise at least one (and preferably a plurality) alignment pin configured to constrain an alignment of a respective resilient member. For example, each alignment pin may pass through a resilient member. The alignment pin(s) may be part of the support frame. For instance, the alignment pin may hold a respective resilient member(s) substantially perpendicular to a surface of the support frame (e.g. the upper compression plate 6) and/or substantially perpendicular to a surface (e.g. a thermal interface surface and/or an upper surface) of a respective cold plate. The alignment pins may extend into a body of the cold plate. That is, the external surface of the cold plate(s) may have a recess into which an alignment pin can pass. For instance, the body of the cold plate may have a channel arranged to accommodate the alignment pin.

In FIGS. 2A, 2B and 2C, a pipework configuration that provides liquid coolant to the cold plates 7, 8 is shown. FIG. 2A is an exploded view in which the pipework is omitted, to aid visualisation of how the pipework fits into the assembly. FIGS. 2B is a side view of the assembly, again with the pipework omitted, and FIG. 2C is an isometric view with the pipework in place, in which the pipework and connectors have been simplified for clarity.

In this embodiment, coolant enters the system through one pipe 13 and is split four ways to the outer cold plates 7, which sit above the optical modules 25. Each of the outer cold plates 7 receives coolant via an inlet and coolant passes through the chamber of each of the cold plates 7 and out of the cold plates 7 via an outlet. Pipes 15 transfer the coolant into the central cold plate 8 in parallel with the coolant from the other outer cold plates 7.

Coolant then exits through one central port 12 of the central cold plate 8, and is transferred away from the cold plates to be re-cycled. The pipes 12, 15 are connected to the cold plates 7, 8 using push fit connectors 14. Nevertheless, various other types of connection, such as olive compression fittings can be used.

Coolant can be provided to the individual cold plates 7, 8 in parallel or series, depending upon the pipe setup, which may be useful for chips with different cooling requirements. As with many cooling systems, the system of this embodiment is a closed loop with coolant flowing in through one pipe and out through another. Nevertheless, this arrangement of pipework could be modified for use with cold plates having an open top to allow coolant to overflow therefrom, as described in International Patent Publication No. 2019/048864.

In a general sense, in the apparatus of this disclosure at least one, and preferably each, cold plate of the first subset of the plurality cold plates comprises: an inlet arranged to receive liquid coolant so as to transfer heat from the electronic devices to the liquid coolant; and an outlet arranged to provide the liquid coolant to the second subset of the plurality of cold plates. In preferred embodiments, the first subset is the cold plates 7 and the second subset is the cold plate 8. The first and second subsets may be connected via various types of piping, conduits, and/or tubing.

At least one, and preferably each, cold plate of the second subset of the plurality cold plates may comprise: an inlet arranged to receive liquid coolant from the first subset of the plurality cold plates so as to transfer heat from the electronic devices to the liquid coolant. At least one, and preferably each, cold plate of the second subset of the plurality cold plates may comprise an outlet arranged to provide the liquid coolant to: one or more further subsets of cold plates of the plurality of cold plates (e.g. for cooling further devices); or a heat exchanger (e.g. to remove heat from the liquid coolant and re-cycle the coolant for further use). The first subset of the plurality of cold plates may comprise a plurality of cold plates arranged to receive liquid coolant in series with each other (i.e. each cold plate of the first subset is in series with each other cold plate of the first subset) or in parallel with each other (i.e. each cold plate of the first subset is in parallel with each other cold plate of the first subset). Similarly, the second subset of the plurality of cold plates may comprise a plurality of cold plates arranged to receive liquid coolant in series with each other (i.e. each cold plate of the second subset is in series with each other cold plate of the first subset) or in parallel with each other (i.e. each cold plate of the second subset is in parallel with each other cold plate of the first subset). In this way, the flow of coolant can be such that electronic devices with the greatest need for cooling receive the lowest temperature (i.e. the freshest) coolant.

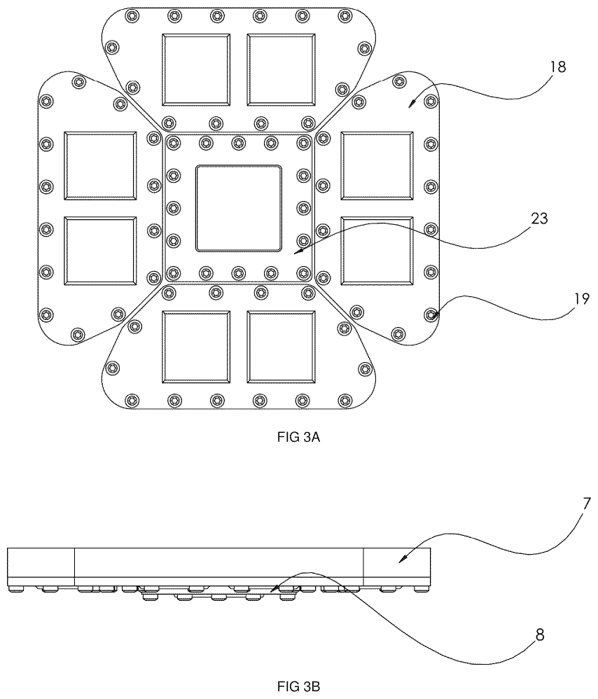

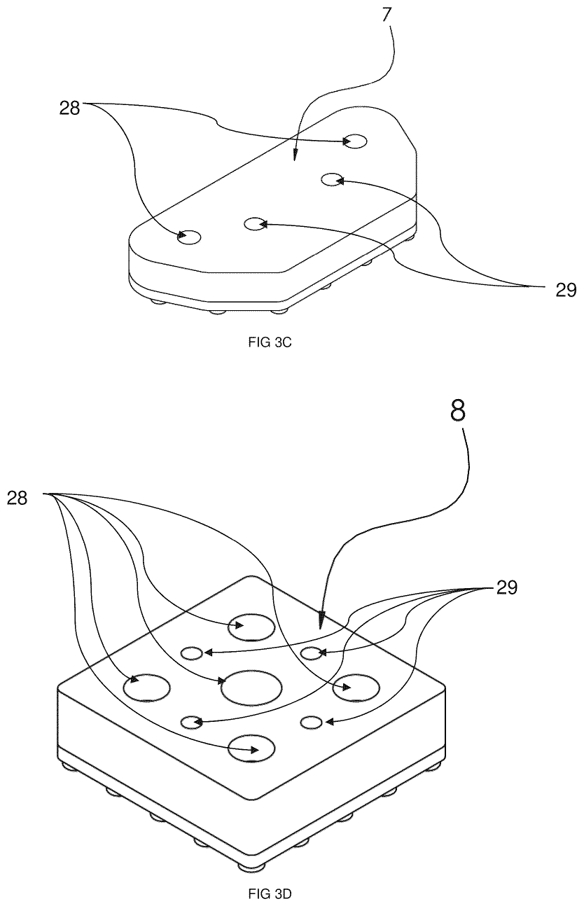

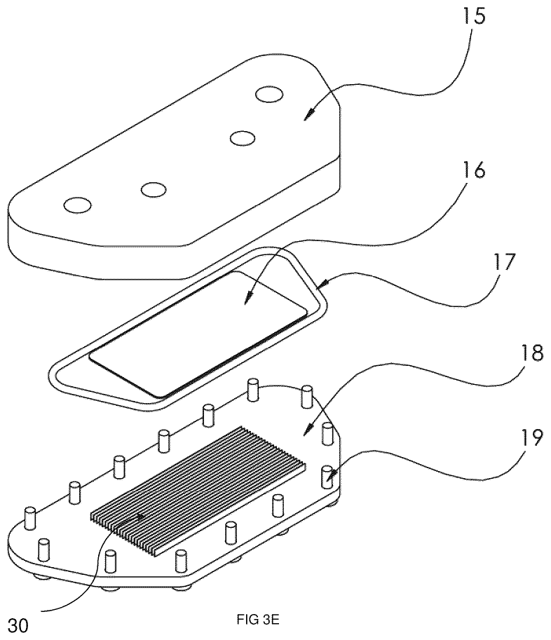

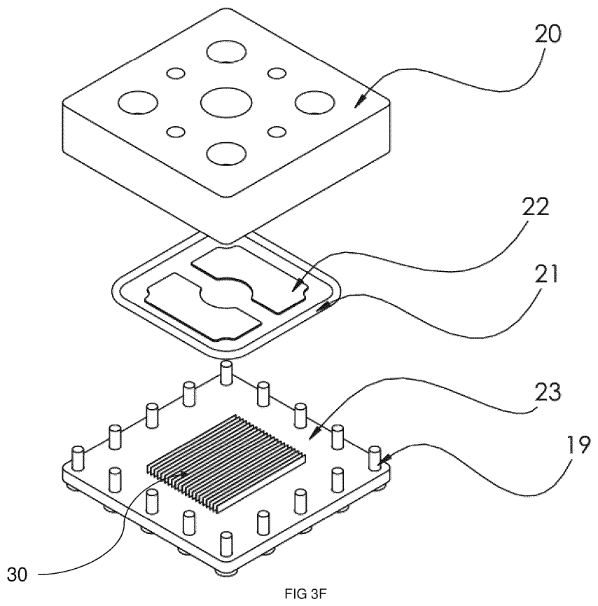

Turning next to FIGS. 3A and 3B, there are shown respectively a bottom and side view of the individual cold plates 7, 8 in their assembled state. FIG. 3A shows the thermal interface surfaces plates of the cold plates on the bottom of the cold plates 7, 8. The thermal interface surfaces are copper surfaces 18, 23 that have raised square faces that mate up with the chips on the circuit board 1. A number of screws 19 are provided around the outside of the copper plates 18, 23 to fasten the copper plates 18, 23 to steel upper portions 15, 20 of the cold plates 7, 8. FIG. 3B displays a side view of the arrangement of FIG. 3A, which shows the bottom of the copper plates 18, 23 (i.e. the thermal interface surfaces) of the central cold plate assembly 8 sitting lower (i.e. closer to the electronic chips or further away from the upper portion 6 of the apparatus) than the corresponding thermal interface surfaces of the outer cold plates 7. This is due to the variable height of the chips 25, 26 on the circuit board 1. Additionally, in use (i.e. when the cold plates 7, 8 are in contact with the chips 25, 26), there may be slight variations in the angles of the upper surfaces of the chips 25, 26 that are visually imperceptible, and the cold plates 7, 8 may rotate slightly to a corresponding angle when a compressive force is applied (i.e. when the support frame is attached to the circuit board). In order to maximise the contact between the cold plates 7, 8 and the chips 25, 26 on the circuit board 1, independence between these cold plates 7, 8 is advantageous, because it is difficult to machine a single heat sink that can accommodate for the different chip heights, which is exacerbated by manufacturing error.

FIGS. 3C and 3D show the two different cold plate 7, 8 sub-assemblies in an isometric view. As described above, the outer cold plate 8 in FIG. 3C has four holes. In FIG. 3C, the two outermost holes 28 are thru holes to allow coolant into and out of the cold plate 7. The inner two holes 29 are for the location bolts 11 that align the cold plate 7 to the upper compression plate 6 and keep the springs 9 vertical. In FIG. 3D, four outer holes 28 and a central hole 28 allow coolant to enter and exit the cold plate 8. Four smaller holes 29 are disposed around the edge of the cold plate 8 and are arranged to receive the location bolts 11 for aligning the cold plate 8 and keeping the springs 9 vertical.

FIGS. 3E and 3F show isometric exploded views of the outer cold plate 7 and the central cold plate 8, respectively. Each cold plate 7, 8 comprises a lower portion 18, 23, which includes a thermal interface surface, and an upper portion 15, 20 for attachment to the support frame of the apparatus. Both cold plates 7, 8 are sealed using o-rings 17, 21 that run around the outer edge of the respective cold plate 7, 8. The o-rings 17, 21 and corresponding grooves in the cold plates 7, 8 are specified in accordance with the British Standard to ensure a high-quality seal, to prevent coolant from leaking out of the cold plates 7, 8. Screws 19 are used to mate the copper skived heat sink plates 18, 23 to the steel upper parts 15, 20 of the cold plates 7, 8.

Both of the heat sinks 18, 23 have protrusions 30 on the lower surface, in the form of skived fins, which provide an increase surface area for the coolant and hence improved thermal cooling for this particular system (although it is also possible to use other materials, manufacturing methods and/or other types of protrusion, e.g., pins, baffles, etc.). To prevent coolant bypassing the fins of the heat sink, a gasket 16, 22 is placed between the fins and upper steel heat sink component 15, 20. The gaskets 16, 22 constrain the flow of coolant within the cold plates 7, 8 to ensure that the coolant passes over the protrusions 30, which improves thermal efficiency.

While FIGS. 3E and 3F show cold plates having a two-part construction, the cold plates could comprise more or fewer components (e.g. comprising three or more parts, or a unitary structure formed by, for example, 3D printing).

In a general sense, the in the apparatus described herein, at least one, and preferably each, cold plate defines an internal volume arranged to receive liquid coolant into the internal volume, so as to transfer heat from the electronic devices to the internal volume of the respective cold plate. As mentioned above, the internal volume could be open or enclosed and in some embodiments, some cold plates may have closed configurations while others have open configurations. The precise arrangement may depend on the nature of the electronic devices that require cooling. In any event, at least one, and preferably each, cold plate comprises one or more protrusions on an internal surface of the internal volume. Such projections may assist with cooling, by dispersing and/or agitating fluid flow within the internal volume (which may ensure that coolant is evenly distributed across the thermal interface surfaces). Moreover, such projections increase the surface area of the internal volume so as to improve heat transfer. The one or more protrusions may comprise any one or more of: skiving; fins; pins; ridges; channels; and baffles. Other types of projection are contemplated.

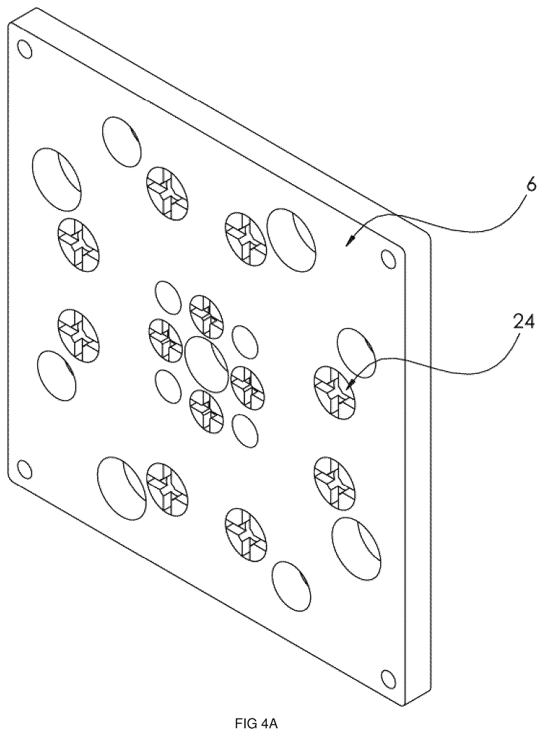

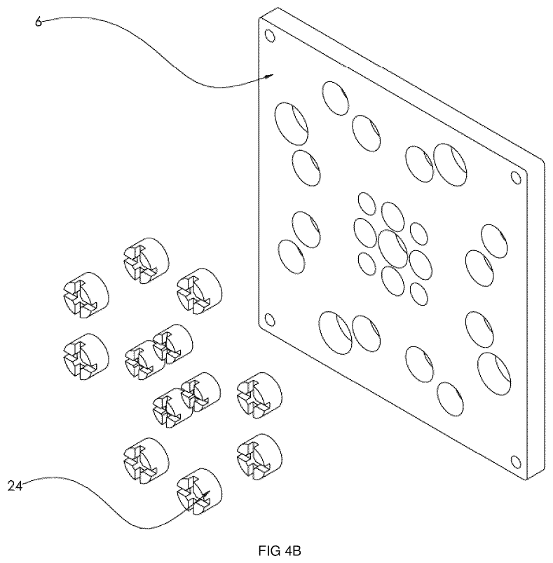

Turning next to FIG. 4A, an isometric view of the upper compression plate 6 assembly is shown. The upper compression plate 6 assembly is sufficiently thick to prevent deformation when under load. The larger thru holes in the upper compression plate allow the pipework 12, 13, 15 to the cold plates 7, 8 to be routed, as best shown in FIGS. 1A, 1B and 2C.

FIG. 4B shows an exploded view of the upper compression plate 6 and its inserts 24. The upper compression plate comprises inserts 24 that seat within the compression plate, which can be used to tune the compression displacement of the resilient members 9 that attach to the cold plates 7, 8. The threaded inserts 24 have a cut-out so that they may be rotated (e.g. to thread the inserts 24 into or out of the compression plate) using a tool to adjust their position (and therefore to adjust the compression of the spring 9 if rotated when the apparatus is installed). The inserts 24 have thru holes drilled in so that the alignment bolts 11 may pass through as displayed in FIG. 2A.

Returning to the generalised terms used previously, at least one, and preferably each, cold plate is adjustably attached to the support frame, so as to permit adjustment of a distance (e.g. as measured in the z-direction, normal to the circuit board) between the support frame and the thermal interface surfaces of at least one, and preferably each, cold plate. The adjustability can be provided by a screw-thread portion (as is the case for the inserts 24), but other position varying means can be used. Equivalently, the distance between the thermal interface surfaces and the circuit board may be adjustable. Each subset of the plurality of cold plates may be moved simultaneously to adjust the distance for that entire subset (i.e. a single adjustment mechanism may be capable of moving a plurality of cold plates). Alternatively, each cold plate may be independently adjustable (i.e. each cold plate may have an independent adjustment mechanism to allow independent motion, independently from all other cold plates). It is preferred that a distance between the support frame and the thermal interface surfaces of at least one, and preferably each, cold plate is independently adjustable.

In preferred embodiments, at least one, and preferably each, resilient member is attached to the support frame by an adjustable attachment portion configured to permit adjustment of a position of a base of the respective resilient member. The base may be considered as being the end of the resilient member that is distal the cold plate. One or more resilient member(s) may be attached (e.g. rigidly attached) to the support frame, for instance by the adjustable attachment portion. The adjustable attachment portion may be, for example, a threaded insert such as the inserts 24 described previously. Preferably, the adjustable attachment portion is threaded into the support frame, and so can be rotated (e.g. screwed) by a user. Nevertheless, the disclosure is not limited to threaded inserts, and any portion of the support frame whose position is adjustable by a user may serve as an adjustable attachment portion for a resilient member. Advantageously, a force exerted on the electronic devices by the plurality of cold plates is adjustable, for example by adjusting a position of a base of the respective resilient member. By bringing the cold plates closer to the circuit board, the resilient members do not compress as much when the cold plates are in contact with the electronic devices, so less force is exerted thereon. Thus, fine control over the magnitude of the forces can be achieved, which can reduce the likelihood of electronic components being crushed.

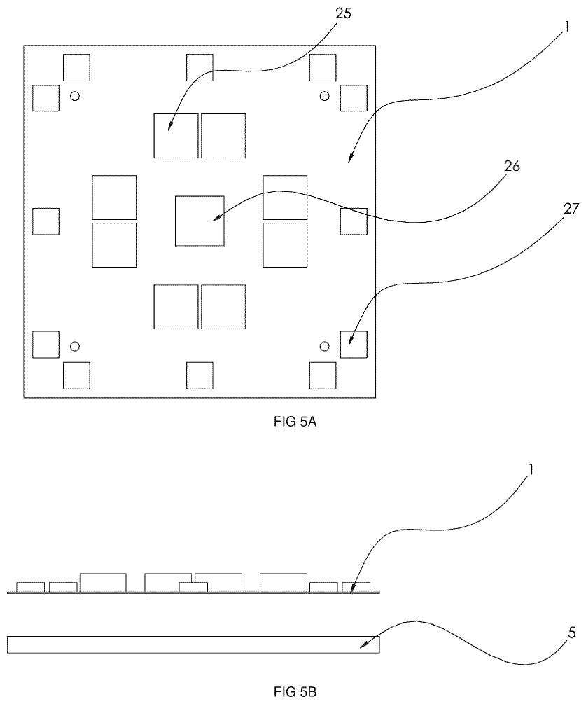

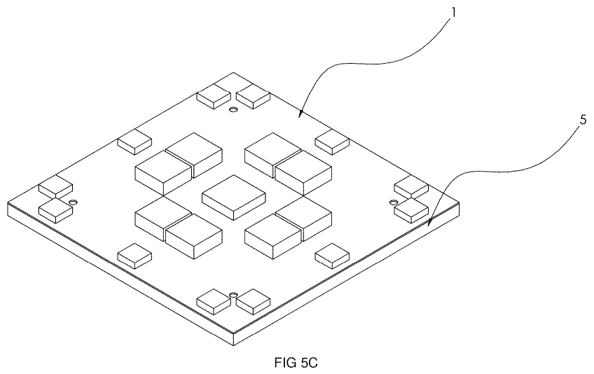

Turning next to FIGS. 5A, 5B and 5C, the circuit board 1 and the lower compression plate 5 are shown in top, side and isometric view, respectively. The circuit board 1 is simplified but comprises one central chip, which is an ASIC chip 26 in this example. There are eight optical chips 25 surrounding the ASIC chip 26. All of these chips 25, 26 are cooled directly by the MHSC of the present disclosure. The path of liquid coolant is determined by the arrangement of pipes 12, 13, 15 to the individual cold plates 7, 8. Coolant is used to cool components whose temperatures are closest to their maximal operating temperatures first using the outer cold plates 7, with the used coolant then being fed to the other cold plates 8 to cool components that are less close to their maximal operating temperatures. In this case, the outer cold plates 7 receive coolant in parallel with each other first. Coolant then flows from the outer cold plates 7 to the central cold plate 8. This flow path arrangement is used because the temperature limits are 75° C. and 90° C. for the optical modules 25 and ASIC chip 26 respectively. Thus, there is a greater need for fresh coolant to be provided to the optical modules 25. The temperature limits are determined by the power of the chips and the number and the layout of cold plates is determined by the location of the heat sources (i.e. the chips that generate heat). Thus, the apparatus of the present disclosure are not limited to this 5-plate arrangement and various different layouts could be provided to cool different chip arrangements. Moreover, different electrical components have different cooling requirements and so these temperature requirements (i.e. 75° C. and 90° C. for the optical modules 25 and ASIC chip 26 respectively) are not intended to be limiting, and electronic devices having any other temperature requirements can be used with embodiments of this disclosure.

FIG. 5A additionally shows smaller chips 27 around the edge of the circuit board 1, which represent other heat sources that could be cooled. For instance, these smaller chips 27 could be cooled by expanding the MSHC assembly to allow further sets of cold plates to be used to cool the smaller chips. Additionally or alternatively, at least one (and optionally all) of the cold plates 7, 8 could have open tops, so that coolant could spill out of the heat sinks 7, 8 and onto nearby chips 27 to cool those chips. In other words, the cold plates 7, 8 could define internal volumes for receiving liquid coolant and an open top over which coolant can overflow, for example as described in XYZ, which is incorporated herein by reference.

In the generalised terms used previously, in preferred embodiments, the first subset of the plurality of cold plates comprises a plurality of, and preferably four, cold plates arranged to receive liquid coolant in parallel and the second subset of the plurality of cold plates is a single cold plate arranged to receive liquid coolant from the first subset of the plurality of cold plates. The first subset of the plurality of cold plates may comprises a plurality of cold plates that are disposed around (e.g. at essentially the same height, but disposed radially around) the second subset of the plurality of cold plates. Such an arrangement can provide efficient coolant to, for example, the circuit board 1 shown in FIGS. 5A, 5B and 5C.

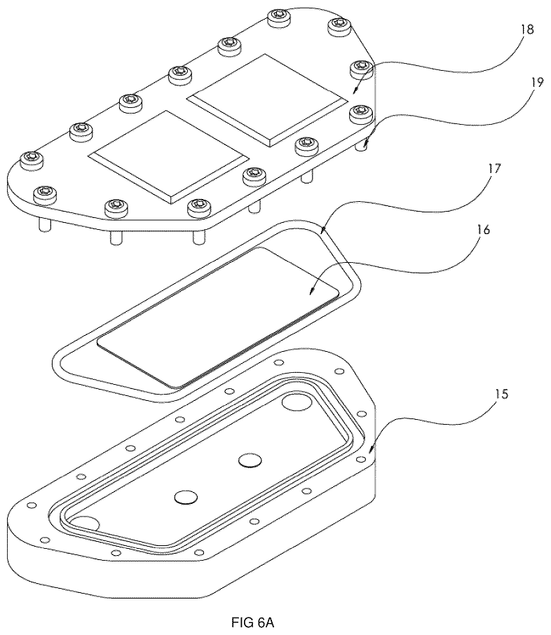

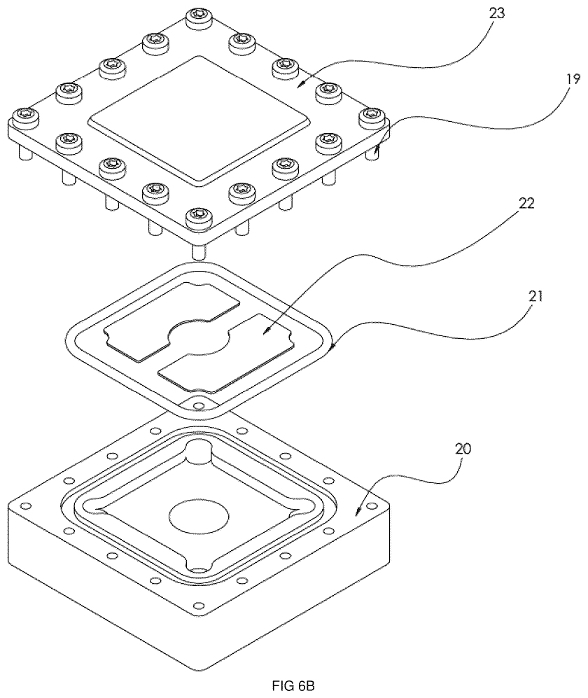

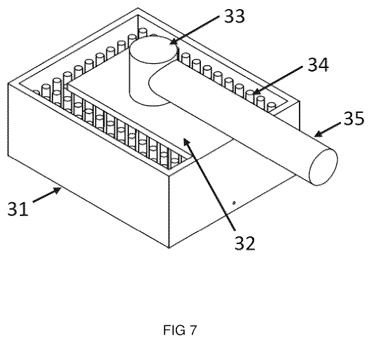

Turning next to FIGS. 6A and 6B, bottom exploded views of the central cold plate 8 and the outer cold plates 7 are shown. Both assemblies have flat gaskets 16, 22, which sit between the copper skived heat sinks 18, 23 and the steel upper components 15, 20. These gaskets 16, 22 are provided to prevent coolant bypassing the protrusions 30 (which are skived fins in this embodiment). There are cut-outs in the gaskets 16, 22 which align using the bosses present on the upper steel components 15, 20, which keeps the gaskets 16, 22 located correctly. The chamber is sealed using the o-rings 21, 17 which sit in a groove around the outside edge of the upper steel parts 15, 20.

Thus, in the general terms used previously, at least one, and preferably each, cold plate may advantageously comprise a gasket therein, the gasket arranged to constrain the liquid coolant to flow around the one or more protrusions. Such gaskets can further improve cooling efficiency. An interior surface of the cold plate (e.g. a bottom surface of an upper portion of the cold plate) and/or a surface of the gasket may comprise one or more bosses arranged to engage a complementary surface of the gasket or interior surface of the cold plate, so as to align the gasket within the cold plate. Such bosses can ensure that the gasket is held in alignment with the cold plate, which reduces the likelihood of the gasket becoming dislodged by coolant flow (which would hinder the functioning of the gasket).

Turning next to FIG. 7, there is shown a heat sink that can serve as a cold plate in the apparatus described herein. The heat sink is shown in FIG. 8C of International Patent Publication No. 2019/048864 and is described in further detail therein. The heat sink can be held in contact with an electronic device. The heat sink defines an internal volume for accumulating and retaining liquid coolant adjacent to the electronic device (or devices). As the liquid coolant flows (by pumping and/or by convection), it is directed to the internal volume of the heat sink, causing improved cooling of the electronic devices. Liquid coolant then flows out of the heat sink internal volume (for example, by overflowing and/or by flowing through holes in the volume) and collects in the bottom of the chassis (e.g. on the surface of the circuit board), in order to cool other electronic devices (for example, other components or ICs on a PCB or mounted in other ways in the chassis). The primary liquid coolant can be cooled by a heat exchanger in the chassis. The heat sink can be provided downstream of any of the cold plates (e.g. cold plates 7, 8) of the above-described embodiments to provide cooling of further electronic devices.

The heat sink of FIG. 7 comprises a pipe 35 and a nozzle 33 that are positioned such that the nozzle 33 is relatively centrally located with respect to the volume defined by the retaining wall 31. A partial lid 32 is provided to cover some of the internal volume. One or more apertures in the partial lid 32 may allow liquid coolant from the nozzle 33 to reach the internal volume. The partial lid 32 may be attached to a part of the nozzle 33, although this may not be needed.

The precise operation of the heat sink and other variations on this heat sink are described in more detail in International Patent Publication No. 2019/048864, which is incorporated by reference. In any case, the partial lid 32 may be connected to the any of the support frames described herein, so as to allow this heat sink to be brought into contact with electronic devices. Alternatively, the partial lid 32 could be omitted and the heat sink could be attached to a support frame by other means. For example, a rigid structure that spans the heat sink may be provided and this structure could be used for attachment to a support frame (including via a resilient member). Moreover, other types of heat sinks (e.g. any of the heat sinks described in International Patent Publication No. 2019/048864) can be adapted to be attached to the support frames described herein. For instance, any of the heat sinks in FIGS. 3, 8, 8A-8F, 9-12, 20-26, 29, 30 of International Patent Publication No. 2019/048864 can be configured for attachment to the support frames of the present disclosure. In any event, in generalised terms, in the apparatus described herein, at least one of the plurality of cold plates comprises a base and a retaining wall that together define a volume for holding liquid coolant, preferably arranged such that liquid coolant overflows over the retaining wall.

While the invention is not limited to comprising a circuit board or an electronic device, some embodiments of the disclosure encompass an apparatus as described herein together with a circuit board and/or a plurality of electronic devices. Thus, the disclosure also provides a system for cooling a plurality of electronic devices disposed on a circuit board, the system comprising: a plurality of electronic devices disposed on a circuit board; and any embodiments of the apparatus described herein, configured to cool the plurality of electronic devices. An upper surface of each electronic device may be in thermal contact with at least one of the thermal interface surfaces of the plurality of cold plates, and the upper surfaces of each of the plurality electronic devices may be at different positions.

Upon reading the embodiments described above, it will be appreciated by the skilled reader that it is preferred for liquid coolant to be kept in liquid form. That is, in other words, there is preferably no phase change of the liquid coolant, since evaporation of liquid coolant may reduce the efficacy of the above-described embodiments, since the ability of gaseous coolant to transfer heat may be reduced.

In preferred embodiments, a first plate (e.g. the upper compression plate 6) of the support frame may be moveable with respect to a second plate (e.g. the lower compression plate 5) such that the displacement between the two plates 5, 6 can be varied. This may be achieved by screwing and/or unscrewing (tightening and/or untightening) the bolts 4 that hold the two plates together. Additionally or alternatively, adjustment of the distance between the plates 5, 6 may be achieved by adjusting the height of the standoffs 10. Various other ways of adjusting the distance between the plates 5, 6 can be provided.

In some embodiments, the first plate can be moved to be at an inclined disposition with respect to the second plate. That is, the amount of displacement between the first and second plates 5, 6 may be variable across a direction of the plates. There may be a non-zero angle between the first and second plates 5, 6. This may be achieved by screwing and/or unscrewing some of the bolts 4 more than others of the bolts 4. Alternatively or additionally, other methods may be used to vary the angle between the first and second plates. These include but are not limited to: adjusting the angle of the standoffs 10; adjusting the height of some of the standoffs 10; changing the angle of the bolts 4. By adjusting the angle so that the first plate is inclined with respect to the second plate, the amount of displacement between first and second plates is independently adjustable between different cold plates or different sets of cold plates (e.g. the displacement between the first and second plates may be independently adjustable for a first set of cold plates and a second set of cold plates). Because the cold plates may be rotatably attached to the first plate, good thermal contact may still be maintained between the electronic devices 25, 26 and the cold plate, despite the first plate being inclined with respect to the second plate.

It will be understood that many variations may be made to the above apparatus, systems and methods whilst retaining the advantages noted previously. For example, where specific types flexible materials have been described, alternative materials can be provided that provide the same or similar functionality. In particular, copper and steel are described, but various other metals (e.g. aluminium) or any other material with high thermal conductivity can be used for providing thermal interfaces. Moreover, where a support frame comprising steel (e.g. steel compression plates) is described, other rigid materials can be used. While pipes have been described for transferring liquid coolant, any conduits, tubing, hosing etc. may be used.

While apparatus comprising cold plates are described, the disclosure also provides an apparatus that employs any type of heat sink, for cooling a plurality of electronic devices disposed on a circuit board. Such an apparatus comprises: a plurality of heat sinks, each heat sink having a thermal interface surface for cooling an electronic device thermally coupled thereto; and a support frame to which each of the plurality of heat sinks is attached, the support frame configured for attachment to the circuit board so as to hold the thermal interface surfaces of the plurality of heat sinks in thermal contact with the plurality of electronic devices; and wherein the support frame is arranged to hold the thermal interface surfaces of a first subset of the plurality of heat sinks at a first position relative to the support frame and to hold the thermal interface surfaces of a second subset of the plurality of heat sinks at a second position relative to the support frame. The heat sinks may be cold plates or any other suitable cooling element. The heat sinks may be configurable in the same way as the cold plates described above. For example, positions of the heat sinks may be independently adjustable (e.g. by tuning resilient members). The heat sinks may be held by a support frame (e.g. including first and second opposing portions, such as plates) as described above. The heat sinks may be brought into contact with the electronic devices. The heat sinks may be liquid cooled (e.g. using series and/or parallel connections) or they may not employ any liquid cooling. The heat sinks may have various protrusions thereon to aid heat transfer.

The particular apparatus described herein is a 3U arrangement, but the apparatus can be readily adapted to 1U, 2U 3U, 4U and 5U (and even higher U) systems.

Some embodiments described herein use liquid cooling and in those embodiments, various fluids (e.g. dielectric fluids) can be used, as can mineral oil and water. The type of coolant can be chosen depending on the particular needs of the electronic devices.

Throughout this disclosure, the terms “chip”, “component” and “device” are used, sometimes interchangeably. These are all examples of electronic devices that the invention can be used to cool.

Embodiments of the disclosure illustrate electronic devices disposed on circuit boards below cold plates. However, it will be understood that the support frames described herein can be used to hold cold plates against vertically-mounted circuit boards, i.e. the support frames may press cold plates horizontally against electronic devices that are mounted on a vertical surface.

Moreover, the above embodiments focus on a case in which only one circuit board is present. Nevertheless, additional circuit boards (e.g. PCBs) can be provided. For example, an optical device may be mounted on an additional PCB that mounts on top of a main PCB. Thus, the support frames described herein, which hold thermal interface surfaces at different positions, can advantageously be used with an arrangement of a plurality of circuit boards. That is, in aspects and embodiments described herein, the support frame may be an apparatus for cooling a plurality of electronic devices disposed on one or more circuit boards.

Each feature disclosed in this specification, unless stated otherwise, may be replaced by alternative features serving the same, equivalent or similar purpose. Thus, unless stated otherwise, each feature disclosed is one example only of a generic series of equivalent or similar features.

As used throughout this disclosure (including in the claims), unless the context indicates otherwise, singular forms of the terms used in this disclosure are to be construed as including the plural form and, where the context allows, vice versa. For instance, unless the context indicates otherwise, a singular reference in this disclosure (including in the claims), such as “a” or “an” (such as an electronic device or a cold plate) means “one or more” (for instance, one or more electronic devices, or one or more cold plates). Throughout the description and claims of this disclosure, the words “comprise”, “including”, “having” and “contain” and variations of the words, for example “comprising” and “comprises” (or similar), mean “including but not limited to”, and are not intended to (and do not) exclude other components.

The use of any and all examples, or exemplary language (“for instance”, “such as”, “for example” and like language) provided in this disclosure, is intended merely to better illustrate the disclosure and does not indicate a limitation on the scope of the disclosure unless otherwise claimed. No language in the specification should be construed as indicating any non-claimed element as essential to the practice of the disclosure.

Any steps described in this specification may be performed in any order or simultaneously unless stated or the context requires otherwise. Moreover, where a step is described as being performed after a step, this does not preclude intervening steps being performed.

All of the aspects and/or features disclosed in this specification may be combined in any combination, except combinations where at least some of such features and/or steps are mutually exclusive. In particular, the preferred features of the disclosure are applicable to all aspects and embodiments of the disclosure and may be used in any combination. Likewise, features described in non-essential combinations may be used separately (not in combination).

A method of manufacturing and/or operating any of the devices (or arrangements of devices) of this disclosure is also provided. The method may comprise steps of providing each of features disclosed and/or configuring the respective feature for its stated function.

1. An apparatus for cooling a plurality of electronic devices disposed on a circuit board, the apparatus comprising:
a plurality of cold plates, each cold plate having a thermal interface surface for cooling an electronic device thermally coupled thereto; and
a support frame to which each of the plurality of cold plates is attached, the support frame configured for attachment to the circuit board so as to hold the thermal interface surfaces of the plurality of cold plates in thermal contact with the plurality of electronic devices; and
wherein the support frame is arranged to hold the thermal interface surface of each of the plurality of cold plates at a different position relative to the support frame.

2. The apparatus of claim 1, wherein the position relative to the support frame comprises an angle relative to the support frame, and the support frame is arranged to hold the thermal interface surface of at least one, and preferably each, cold plate at a different angle relative to the support frame.

3. The apparatus of claim 1, wherein the position relative to the support frame comprises a distance from the support frame, and the support frame is arranged to hold the thermal interface surfaces of a first subset of the plurality of cold plates at a first distance from the support frame and to hold the thermal interface surfaces of a second subset of the plurality of cold plates at a second distance from the support frame.

4. The apparatus of claim 1, wherein at least one, and preferably each, cold plate is rotatably attached to the support frame.

5. The apparatus of claim 1, wherein at least one, and preferably each, cold plate is attached to the support frame by one or more resilient members, the one or more resilient members configured to force the respective at least one cold plate away from the support frame.

6. The apparatus of claim 5, further comprising at least one alignment pin configured to constrain an orientation of at least one, and preferably each, resilient member.

7. The apparatus of claim 1, wherein the support frame comprises a first portion to which each of the plurality of cold plates are attached and a second portion that opposes the first portion, preferably wherein one or more resilient members are attached to the first portion of the support frame.

8. The apparatus of claim 7, wherein the first portion and the second portion of the support frame are configured to be drawn together, so as to hold the thermal interface surfaces of the plurality of cold plates in thermal contact with the plurality of electronic devices.

9. The apparatus of claim 7, further comprising one or more projections between the first portion and the second portion of the support frame, the one or more projections configured to limit a distance between the first portion and the second portion of the support frame.

10. The apparatus of claim 7, wherein:
the first portion of the support frame is a plate; and/or the second portion of the support frame is a plate; and/or
the support frame is configured to compress the plurality of electronic devices between the plurality of cold plates and the circuit board.

11. The method of claim 1, wherein:
at least one, and preferably each, cold plate is adjustably attached to the support frame, so as to permit adjustment of a distance between the support frame and the thermal interface surfaces of at least one, and preferably each, cold plate; and/or
a distance between the support frame and the thermal interface surfaces of at least one, and preferably each, cold plate is independently adjustable.

12. The apparatus of claim 1, wherein a force exerted on the electronic devices by at least one of the plurality of cold plates is adjustable, preferably by adjusting a position of a base of a respective resilient member.

13. The apparatus of claim 1, when dependent on claim 5 or claim 6, wherein at least one, and preferably each, resilient member is attached to the support frame by an adjustable attachment portion configured to permit adjustment of a position of a base of the respective resilient member.

14. The apparatus of claim 13, wherein the adjustable attachment portion is threaded into the support frame.

15. The apparatus of claim 1, wherein the plurality of cold plates comprises a first subset and a second subset, and at least one, and preferably each, cold plate of the first subset of the plurality cold plates comprises:
an inlet arranged to receive liquid coolant so as to transfer heat from the electronic devices to the liquid coolant; and
an outlet arranged to provide the liquid coolant to the second subset of the plurality of cold plates.

16. The apparatus of claim 1, wherein the plurality of cold plates comprises a first subset and a second subset, and wherein at least one, and preferably each, cold plate of the second subset of the plurality cold plates comprises:
an inlet arranged to receive liquid coolant from the first subset of the plurality cold plates so as to transfer heat from the electronic devices to the liquid coolant; and preferably
an outlet arranged to provide the liquid coolant to:
one or more further subsets of cold plates of the plurality of cold plates; or
a heat exchanger.

17. The apparatus of claim 1, wherein the plurality of cold plates comprises a first subset and a second subset, and wherein:
the first subset of the plurality of cold plates comprises a plurality of cold plates arranged to receive liquid coolant in series or in parallel; and/or
the second subset of the plurality of cold plates comprises a plurality of cold plates arranged to receive liquid coolant in series or in parallel.

18. The apparatus of claim 1, wherein the plurality of cold plates comprises a first subset and a second subset, and wherein:
the first subset of the plurality of cold plates comprises a plurality of, and preferably four, cold plates arranged to receive liquid coolant in parallel and the second subset of the plurality of cold plates is a single cold plate arranged to receive liquid coolant from the first subset of the plurality of cold plates; and/or
the first subset of the plurality of cold plates comprises a plurality of cold plates that are disposed around the second subset of the plurality of cold plates.

19. The apparatus of claim 1, wherein at least one, and preferably each, cold plate defines an internal volume arranged to receive liquid coolant into the internal volume, so as to transfer heat from the electronic devices to the internal volume of the respective cold plate.

20. The apparatus of claim 19, wherein at least one, and preferably each, cold plate comprises one or more protrusions on an internal surface of the internal volume, preferably wherein the one or more protrusions comprise any one or more of: skiving; fins; pins; ridges;
channels; and baffles.

21. The apparatus of claim 20, wherein at least one, and preferably each, cold plate comprises a gasket therein, the gasket arranged to constrain the liquid coolant to flow around the one or more protrusions.

22. The apparatus of claim 21, wherein an interior surface of the cold plate and/or a surface of the gasket comprises one or more bosses arranged to engage a complementary surface of the gasket or interior surface of the cold plate, so as to align the gasket within the cold plate.

23. The apparatus of claim 1, wherein at least one of the plurality of cold plates comprises a base and a retaining wall that together define a volume for holding liquid coolant, preferably arranged such that liquid coolant overflows over the retaining wall.

24. A system for cooling a plurality of electronic devices disposed on a circuit board, the system comprising:
a plurality of electronic devices disposed on a circuit board; and
an apparatus, configured to cool the plurality of electronic devices, the apparatus comprising:
a plurality of cold plates, each cold plate having a thermal interface surface for cooling an electronic device thermally coupled thereto; and
a support frame to which each of the plurality of cold plates is attached, the support frame configured for attachment to the circuit board so as to hold the thermal interface surfaces of the plurality of cold plates in thermal contact with the plurality of electronic devices; and
wherein the support frame is arranged to hold the thermal interface surface of each of the plurality of cold plates at a different position relative to the support frame.

25. The system of claim 24, wherein an upper surface of each electronic device is in thermal contact with at least one of the thermal interface surfaces of the plurality of cold plates, wherein the upper surfaces of each of the plurality electronic devices are at different positions relative to the support frame.
